(19) United States
(12) Patent Application Publication
(10) Pub. No.: US 2026/0269805 A1
(43) Pub. Date: Sep. 10, 2026

(54) ACOUSTIC WAVE DEVICE, METHOD FOR MANUFACTURING ACOUSTIC WAVE DEVICE, AND COMMUNICATION DEVICE

(71) Applicant: KYOCERA CORPORATION, Kyoto-shi, Kyoto (JP)

(72) Inventor: Yoshihide IKEGAMI, Kyoto-shi, Kyoto (JP)

(73) Assignee: KYOCERA CORPORATION, Kyoto-shi, Kyoto (JP)

(21) Appl. No.: 18/875,951

(22) PCT Filed: Jun. 1, 2023
(86) PCT No.: PCT/JP2023/020401

§ 371 Date: Dec. 17, 2024

(30) Foreign Application Priority Data
Jun. 23, 2022 (JP) 2022-101401

(51) Int. Cl. H03H 9/05; H03H 3/08; H03H 9/02

(52) U.S. Cl. CPC H03H 9/0523; H03H 3/08; H03H 9/02015; H03H 9/059

(57) ABSTRACT

Bonding strength between an electrode layer and an under bump metal can be ensured. An acoustic wave device includes a piezoelectric layer, an electrode layer located on an upper surface of the piezoelectric layer, an under bump metal, and a bump, in which the under bump metal includes a first region directly bonded to the piezoelectric layer and a second region bonded to the electrode layer, and at least part of the first region and at least part of the bump overlap each other when the piezoelectric layer is viewed in plan view.

### TECHNICAL FIELD

The present disclosure relates to an acoustic wave device.

### BACKGROUND OF INVENTION

In recent years, in order to reduce the size of acoustic wave devices, acoustic wave devices assembled by a flip-chip bonding method have come into widespread use. In this method, a bump is formed on an electrode pad on a piezoelectric layer constituting the acoustic wave device, and an electrode layer and an input/output electrode pad or a ground electrode pad provided in a package are electrically connected and mechanically bonded to each other via the bump.

### CITATION LIST

### Patent Literature

Patent Document 1: JP 2002-261560 A

### SUMMARY

An acoustic wave device according to an aspect of the present disclosure includes a piezoelectric layer, an electrode layer located on an upper surface of the piezoelectric layer, an under bump metal, and a bump, in which the under bump metal includes a first region directly bonded to the piezoelectric layer and a second region bonded to the electrode layer, and at least part of the first region overlaps with at least part of the bump when the piezoelectric layer is viewed in plan view.

### BRIEF DESCRIPTION OF THE DRAWINGS

FIG. 1 is a cross-sectional structure diagram of an acoustic wave device according to a first embodiment of the present disclosure.

FIG. 2 is a plan view of the acoustic wave device according to the first embodiment of the present disclosure.

FIG. 3 is a cross-sectional structure diagram of an acoustic wave device according to a third embodiment of the present disclosure.

FIG. 4 is a cross-sectional structure diagram of a general acoustic wave device.

### DESCRIPTION OF EMBODIMENTS

The bumps not only function to electrically connect the acoustic wave device and the package but also function to mechanically fix the acoustic wave device to the package. However, in the related art, the bonding strength between the acoustic wave device and the bump is not necessarily sufficient.

### First Embodiment

Hereinafter, an embodiment (hereinafter, also written as “present embodiment”) according to an aspect of the present disclosure will be described in detail with reference to the drawings. In the drawings, the same or corresponding parts are denoted by the same reference numerals, and description thereof will not be repeated.

### Comparative Example: Cross-Sectional Structure of General Acoustic Wave Device

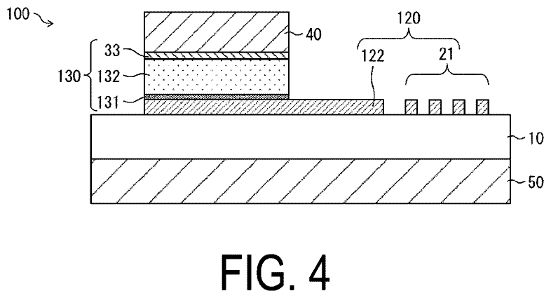

FIG. 4 is a cross-sectional structure diagram of a general acoustic wave device 100. The acoustic wave device 100 includes a support substrate 50, a piezoelectric layer 10, an electrode layer 120, an under bump metal 130, and a bump 40, which are superimposed on one another.

The piezoelectric layer 10 is a thin film formed of a piezoelectric material. An example of the piezoelectric material is LT (lithium tantalate: LiTaO₃) or LN (lithium niobate: LiNbO₃). The piezoelectric layer 10 may be a piezoelectric single crystal such as quartz crystal or a piezoelectric ceramic such as a lead zirconate titanate ceramic. In the present embodiment, LT is used.

The piezoelectric layer 10 is formed on the support substrate 50. The support substrate 50 may be provided with a cavity portion between the support substrate 50 and the piezoelectric layer 10. A thin SiO₂ layer may be provided between the piezoelectric layer 10 and the support substrate 50, or an acoustic reflection film in which a plurality of low acoustic impedance layers made of, for example, SiO₂ and a plurality of high acoustic impedance layers made of, for example, HfO₂ are alternately layered may be provided. Alternatively, the piezoelectric layer 10 may have a sufficient thickness without the support substrate 50.

The electrode layer 120 includes an IDT electrode portion 21 and a pad portion 122. An electrode layer 20 is generally made of a material containing aluminum, and is patterned by etching an aluminum alloy (AlCu) film in the present embodiment. Alternatively, the electrode layer 120 may be formed using another metal such as copper (Cu) or an alloy.

The IDT electrode portion 21 is a comb-shaped electrode that generates an acoustic wave in the acoustic wave device. The IDT electrode portion 21 includes a pair of electrodes for applying an AC voltage. The pad portion 122 is connected to the IDT electrode portion 21.

The under bump metal 130 is an underlying layer. The under bump metal 130 includes a bonding layer 131, a metal layer 132, and a melt layer 33, which are superimposed on one another in this order.

Since aluminum is easily oxidized, the bump 40 cannot be bonded with good adhesiveness to the electrode layer 120 made of an aluminum alloy.

Therefore, an under bump metal 30 is inserted between the electrode layer 120 and the bump 40 as an intermediate layer, and acts as an intermediary between the electrode layer 120 and the bump 40. The under bump metal 130 is characterized in that the bonding layer 131, the metal layer 132, and the melt layer 33 are formed with substantially uniform thicknesses.

The bonding layer 131 is made of chromium (Cr), titanium (Ti), or the like, and serves to strengthen the bonding between the aluminum alloy and another metal. The metal layer 132 is made of nickel (Ni) or the like, and is plating that ensures corrosion resistance and electrical conductivity as an under bump metal. In addition, the metal layer 132 reduces diffusion of the bump 40 when the bump 40 is melted, which will be described later. The melt layer 33 is a layer for improving wettability of the bump 40, and is made using gold (Au) or the like.

The bump 40 is a so-called solder, and is made of tin (Sn), silver (Ag), copper (Cu), or the like. The bump 40 interweaves and bonds with the melt layer 33. After bump bonding, the melt layer 33 is integrated with the bump 40, and the boundary between the molten layer 33 and the bump 40 may not be clear.

Since aluminum and an aluminum alloy are easily oxidized, the electrode layer 120 and the bump 40 are bonded to each other via the under bump metal 130. However, the interface between the electrode layer 120 and the bump 40 is easily oxidized, thus making it difficult to obtain bonding strength. In particular, depending on the state of oxidation, bonding strength may not be obtained at the interface between the electrode layer 120 and the under bump metal 130, resulting in less stable bonding strength for the entire acoustic wave device 100.

### Cross-Sectional Structure

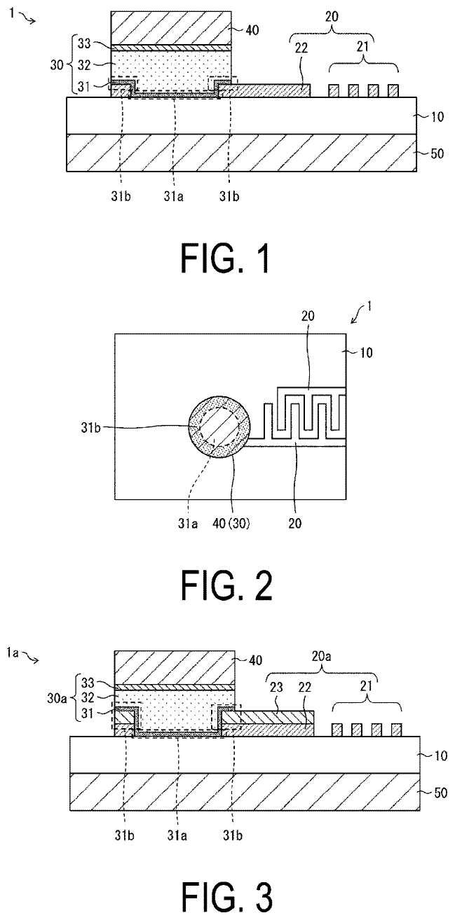

An acoustic wave device 1 according to a first embodiment will be described below. FIG. 1 is a cross-sectional structure diagram of the acoustic wave device 1 according to the first embodiment of the present disclosure. Similarly to the acoustic wave device 100, the acoustic wave device 1 includes the support substrate 50, the piezoelectric layer 10, the electrode layer 20, the under bump metal 30, and the bump 40. The configurations of the electrode layers 20 and 120 and the under bump metals 30 and 130 are different between the acoustic wave device 1 and the acoustic wave device 100.

The electrode layer 20 includes the IDT electrode portion 21 and a pad portion 22. The shape of the pad portion 22 differs between the electrode layer 20 and the electrode layer 120 of the comparative example.

The pad portion 22 has an opening at its center. The shape of the opening is not limited and may be, for example, circular.

The under bump metal 30 includes a bonding layer 31, a metal layer 32, and the melt layer 33, which are superimposed on one another in this order. That is, the shapes of the bonding layer and the metal layer differ between the under bump metal 30 and the under bump metal 130.

The bonding layer 31 is formed and enters the opening of the pad portion 22. The metal layer 32 is formed on the bonding layer 31 and closes the recessed portion of the bonding layer 31 while forming the same shape as the opening of the pad portion 22.

### First Region 31a and Second Region 31b

As a result, a first region 31a in which the bonding layer 31 and the piezoelectric layer 10 are directly bonded and a second region 31b in which the bonding layer 31 and the electrode layer 20 are bonded are formed.

Since the aluminum alloy has the property of being easily oxidized as described above, the surface property of the interface of the electrode layer 20 is unstable. Therefore, depending on the oxidation state, the aluminum alloy of the electrode layer 20 and the chromium of the bonding layer 31 are not bonded to each other in some cases. On the other hand, the bonding strength between the chromium used for the bonding layer 31 and LT of the piezoelectric layer 10 is stable (constant strength). Therefore, by bonding the bonding layer 31 and the piezoelectric layer 10 to each other in the first region 31a, the bonding strength of the acoustic wave device 1 can be increased. That is, the bonding strength of the acoustic wave device 1 is higher than the bonding strength of the acoustic wave device 100, and the under bump metal 30 is less likely to be peeled off.

In the second region 31b, the aluminum alloy of the electrode layer 20 is in close contact with the chromium of the bonding layer 31, thereby ensuring electrical conduction between the electrode layer 20 and the under bump metal 30.

Therefore, in the acoustic wave device 1, the bonding strength of the under bump metal 30 is ensured in the first region 31a, and the electrical conduction of the under bump metal 30 is ensured in the second region 31b.

### Arrangement in Plan View

FIG. 2 is a plan view of the acoustic wave device 1 according to the first embodiment of the present disclosure. As illustrated in FIG. 2, when the piezoelectric layer 10 is viewed in plan view, at least part of the first region 31a and at least part of the bump 40 overlap each other. Therefore, the stability of the bonding strength between the under bump metal 30 and the piezoelectric layer 10 can be ensured at the bonding portion of the bump 40 in plan view. As a result, the under bump metal 30 and the electrode layer 20 can be firmly bonded to each other.

Here, in the comparative example, the mechanical strength is secured by the bonding strength between the electrode layer 20 and the bonding layer 31. However, since the surface property of aluminum used for the electrode layer 20 is poor, there is a disadvantage in that it is difficult to obtain bonding strength. On the other hand, in the present embodiment, the piezoelectric layer 10 and the bonding layer 31 are directly bonded to each other in the first region, and the mechanical strength is secured by the bonding strength of the first region. That is, when the piezoelectric layer 10 is viewed in plan view, the first region 31a is located within the bump 40.

When the piezoelectric layer 10 is viewed in plan view, the center of the bump 40 and the center of the first region 31a may overlap each other. The expression “center” may be the center of a circle when the shape of the bump 40 and the first region 31a is a circle, or may be the center of gravity when the shape is a rectangle. The center of the bump 40 and the center of the first region 31a are not necessarily required to exactly coincide with each other when the piezoelectric layer 10 is viewed in plan view, and may be within a certain range. As the range, for example, when the piezoelectric layer 10 is viewed in plan view, a region corresponding to the central 30% surface area of the bump 40 in the region where the bump 40 is present is the center. For example, when the piezoelectric layer 10 is viewed in plan view, a region corresponding to the central 30% surface area of the first region 31a is the center.

When the piezoelectric layer 10 is viewed in plan view, the first region 31a may be located within the bump 40.

The surface area of the first region 31a may be larger than the surface area of the second region 31b. In these cases, the bonding strength of the under bump metal 30 to the piezoelectric layer 10 and the electrode layer 20 can be ensured.

The pad portion 22 of the electrode layer 20 has a circular opening, and the under bump metal 30 and the piezoelectric layer 10 are bonded to each other in the opening. That is, the first region 31a is located in the opening. The opening in the electrode layer 20 is not limited to a circular shape and may have any shape (for example, a rectangular shape) as long as the pad portion 22 surrounds at least part of the first region 31a. That is, the second region 31b only needs to surround at least part of the first region 31a. This increases the possibility of electrical conduction between the under bump metal 30 and the electrode layer 20.

The bonding strength between the electrode layer 20 and the bonding layer 31 tends to be higher than the bonding strength between the piezoelectric layer 10 and the bonding layer 31, although it lacks stability. Therefore, the second region surrounds the first region, whereby the bonding strength can be increased.

### Second Embodiment

Another embodiment of the present disclosure will be described below. For convenience of description, members having the same functions as those of the members described in the above-described embodiment are denoted by the same reference signs, and description thereof is not repeated.

The thick piezoelectric layer 10 is bonded to the support substrate 50, and the piezoelectric layer 10 is ground to be thin. Alternatively, the piezoelectric layer 10 may be formed on the support substrate 50 by any method such as vapor deposition, plating, or sputtering.

An electrically conductive layer is formed on the piezoelectric layer 10 by any method such as vapor deposition, plating, or sputtering (first step). Thereafter, in order to form a predetermined shape (the IDT electrode portion 21 and the pad portion 22) in the electrically conductive layer, a mask is used and part of the electrically conductive layer is removed by wet etching or dry etching to form the electrode layer 20 (second step).

Thereafter, a mask is used, and a pattern of the under bump metal 30 is formed to be in contact with the piezoelectric layer 10 and the opening of the electrode layer 20 by any method such as vapor deposition, plating, or sputtering (third step).

After the second step, the third step may be performed without performing the oxide film removal and smoothing treatment on the upper surface of the electrode layer. This is because there is no sufficient time for the electrode layer 20 to be oxidized since the third step is performed immediately after the second step.

Then, the bump 40 is formed on the under bump metal 30 (fourth step).

Therefore, since the bonding surface between the piezoelectric layer 10 and the under bump metal 30 is kept clean before the third step, the piezoelectric layer 10 and the under bump metal 30 can be stably bonded without performing cleaning.

### Third Embodiment

FIG. 3 is a cross-sectional structure diagram of an acoustic wave device la according to a third embodiment of the present disclosure. In the third embodiment, a low-resistance layer 23 is added to the electrode layer 20 in an electrode layer 20a. The low-resistance layer 23 is an aluminum film formed on the pad portion 22.

By forming the low-resistance layer 23, the resistance of the wiring from the pad portion 22 to the IDT electrode portion 21 can be reduced, and the effect of reducing power consumption can be obtained. As a result, heat generation is reduced and resistance is reduced, and thus loss characteristics are improved.

In the present embodiment, in addition to the interface between the pad portion 22 and the bonding layer 31, the interface between the low-resistance layer 23 and the bonding layer 31 corresponds to the second region 31b.

### Variations

In the first to third embodiments, the under bump metal 30 has the bonding layer 31 in both the first region 31a and the second region 31b, but the bonding layer 31 does not need to be provided in the second region 31b. That is, in the second region 31b, the electrode layer 20 and the metal layer 32 may be bonded to each other.

In the first to third embodiments, the first region is located in the opening of the pad portion 22 and the second region is disposed to surround the first region in plan view, but the present disclosure is not limited to this. For example, the first region may be formed around the pad portion 22 connected to the IDT electrode portion 21 except for the wiring portion to the IDT electrode portion 21. That is, the second region is surrounded by the first region, and the first region has a C-shape.

In this case, the piezoelectric layer 10 and the bonding layer 31 are firmly bonded to each other at the outer periphery of the pad portion 22, thereby allowing the piezoelectric layer 10 and the bonding layer 31 not to be gradually peeled off from the outer periphery of the bonding surface.

In the first to third embodiments, a surface acoustic wave (SAW) has been described as an acoustic wave device, but the present disclosure is not limited thereto. The acoustic wave device may be, for example, a bulk acoustic wave (BAW).

### Conclusion

An acoustic wave device according to a first aspect of the present disclosure includes a piezoelectric layer, an electrode layer located on an upper surface of the piezoelectric layer, an under bump metal, and a bump, in which the under bump metal includes a first region bonded to the piezoelectric layer and a second region bonded to the electrode layer, and at least part of the first region and at least part of the bump overlap each other when the piezoelectric layer is viewed in plan view.

According to the above configuration, the stability of the bonding strength between the under bump metal and the piezoelectric layer at the bump bonding portion can be ensured in plan view. As a result, the under bump metal and the electrode layer can be firmly bonded to each other.

In an acoustic wave device according to a second aspect of the present disclosure, in the first aspect, the first region may be located within the bump when the piezoelectric layer is viewed in plan view.

According to the above-described configuration, since the first region is located within the bump in plan view, the bump and the first region overlap each other, and the stability of the bonding strength can be ensured.

In an acoustic wave device according to a third aspect of the present disclosure, in the first or second aspect, a surface area of the first region may be larger than a surface area of the second region.

According to the configuration described above, the bonding strength between the electrode layer and the under bump metal can be ensured by the second region, and the under bump metal can be stably bonded to the piezoelectric layer by the first region.

In an acoustic wave device according to a fourth aspect of the present disclosure, in any one of the first to third aspects, the second region may surround the first region.

According to the configuration described above, the under bump metal and the electrode layer can be bonded to each other via the second region, and electrical conduction is easily ensured. According to the above-described configuration, the second region surrounds the first region, and thus the bonding strength can be ensured.

In an acoustic wave device according to a fifth aspect of the present disclosure, in any one of the first to fourth aspects, the electrode layer may include an IDT electrode portion and a pad portion, and the first region may be located in an opening of the pad portion.

According to the above-described configuration, the acoustic wave device can also be formed by a bulk acoustic wave (BAW).

In an acoustic wave device according to a sixth aspect of the present disclosure, in any one of the first to fifth aspects, a material of the upper surface of the electrode layer may contain aluminum.

According to the above configuration, the bonding can be stabilized even on the surface of aluminum where bonding is difficult to stabilize.

In an acoustic wave device according to a seventh aspect of the present disclosure, in any one of the first to sixth aspects, the second region does not need to include a layer bonding the electrode layer and the under bump metal.

According to the above-described configuration, stable bonding can be achieved without a bonding layer.

In an acoustic wave device according to an eighth aspect of the present disclosure, in any one of the first to seventh aspects, the piezoelectric layer may be made of lithium tantalate or lithium niobate, and the under bump metal may include a layer made of chromium or titanium.

According to the above configuration, the under bump metal can be stably bonded.

A method for manufacturing an acoustic wave device according to a ninth aspect of the present disclosure includes: a first step of providing an electrically conductive layer on a piezoelectric layer; a second step of removing part of the electrically conductive layer to form an electrode layer in which an electrode is formed; a third step of forming an under bump metal in contact with the piezoelectric layer and an opening of the electrode layer; and a fourth step of forming a bump on the under bump metal.

According to the above-described configuration, in the second step, the region where the piezoelectric layer is formed is covered with the electrode layer, thus the bonding surface between the piezoelectric layer and the under bump metal is kept clean.

In a method for manufacturing an acoustic wave device according to a tenth aspect of the present disclosure, in any one of the first to ninth aspects, the oxide film removal and smoothing treatment do not need to be performed on the upper surface of the electrode layer before the third step.

According to the above-described configuration, since the bonding surface between the piezoelectric layer and the under bump metal is kept clean, the piezoelectric layer and the under bump metal can be stably bonded without performing cleaning.

According to the configuration described above, the communication device can perform filtering using the acoustic wave device.

### Supplementary Note

The present disclosure is not limited to each of the embodiments described above, and various modifications can be made within the scope indicated by the claims, and an embodiment obtained by appropriately combining technical means disclosed in different embodiments is also included in the technical scope of the present disclosure.

### REFERENCE SIGNS

1, 1a, 100 Acoustic wave device
10 Piezoelectric layer
20, 120 Electrode layer
21 IDT electrode portion
22, 122 Pad portion
23 Low-resistance layer
30, 130 Under bump metal
31, 131 Bonding layer
31a First region
31b Second region
32, 132 Metal layer
33 Melt layer
40 Bump
50 Support substrate

1. An acoustic wave device comprising:
a piezoelectric layer;
an electrode layer located on an upper surface of the piezoelectric layer;
an under bump metal; and
a bump, wherein
the under bump metal comprises:
a first region bonded to the piezoelectric layer; and
a second region bonded to the electrode layer, and
at least part of the first region and at least part of the bump overlap each other when the piezoelectric layer is viewed in plan view.

2. The acoustic wave device according to claim 1, wherein
the first region is located within the bump when the piezoelectric layer is viewed in plan view.

3. The acoustic wave device according to claim 1, wherein
a surface area of the first region is greater than a surface area of the second region.

4. The acoustic wave device according to claim 1, wherein
the second region surrounds the first region.

5. The acoustic wave device according to claim 1, wherein
the electrode layer comprises an IDT electrode portion and a pad portion, and
the first region is located in an opening of the pad portion.

6. The acoustic wave device according to claim 1, wherein
a material of an upper surface of the electrode layer contains aluminum.

7. The acoustic wave device according to claim 1, wherein
the second region does not comprise a layer bonding the electrode layer and the under bump metal.

8. The acoustic wave device according to claim 1, wherein
the piezoelectric layer is made of lithium tantalate or lithium niobate, and
the under bump metal comprises a layer of chromium or titanium.

9. A method for manufacturing an acoustic wave device comprising:
providing an electrically conductive layer on a piezoelectric layer;
removing part of the electrically conductive layer to form an electrode layer in which an electrode is formed;
forming an under bump metal in contact with the piezoelectric layer and an opening of the electrode layer; and
forming a bump on the under bump metal.

10. The method for manufacturing an acoustic wave device according to claim 9, wherein
after the forming of the electrode layer, the forming of the under bump metal is performed without performing oxide film removal and smoothing treatment on an upper surface of the electrode layer.
